(19) United States
(12) Patent Application Publication
(10) Pub. No.: US 2026/0147267 A1
(43) Pub. Date: May 28, 2026

(54) EUV MASK INSPECTING METHODS AND SYSTEMS

(71) Applicant: Taiwan Semiconductor Manufacturing Company, Ltd., Hsinchu (TW)

(72) Inventors: Chun-Lung LU, Hsinchu (TW); Hao-Ming CHANG, Hsinchu (TW); Hsin-Fu TSENG, Hsinchu (TW); Chun-Lang CHEN, Hsinchu (TW)

(73) Assignee: Taiwan Semiconductor Manufacturing Company, Ltd., Hsinchu (TW)

(21) Appl. No.: 18/959,976

(22) Filed: Nov. 26, 2024

(51) Int. Cl. G03F 1/22; G01B 15/08; G03F 7/00

(52) U.S. Cl. CPC G03F 1/22; G01B 15/08; G03F 7/70625; G03F 7/706841; G03F 7/706847; G03F 7/7085

(57) ABSTRACT

A method for inspecting a patterning mask includes radiating an extreme ultraviolet (EUV) beam to a surface of the patterning mask and directing a reflected EUV beam from the surface of the patterning mask to an image sensor. The method further includes generating an image of the surface of the patterning mask based on the reflected EUV beam and determining a critical dimension uniformity (CDU) of the patterning mask based on the image of the surface of the patterning mask.

### BACKGROUND

During an integrated circuit (IC) design, a number of patterns of the IC, for different steps of IC processing, are generated on a substrate. The patterns may be produced by projecting, e.g., imaging, by extreme ultraviolet (EUV) radiation, layout patterns of a patterning mask on a photoresist layer on a wafer. A lithographic process transfers the layout patterns of the patterning mask to the photoresist layer of the wafer such that etching, implantation, or other steps are applied only to predefined regions of the wafer. It is desirable to inspect the patterning mask before being used in the lithographic process.

### BRIEF DESCRIPTION OF THE DRAWING

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a schematic view of an EUV lithography system, according to embodiments of the disclosure.

FIG. 2 illustrates a schematic view of a patterning mask inspecting device, according to embodiments of the disclosure.

FIG. 3 illustrates a perspective view of a structure of a portion of the patterning mask, according to embodiments of the disclosure.

FIG. 4A illustrates an image of the patterning mask, according to embodiments of the disclosure.

FIG. 4B illustrates a diagram of a dummy test critical dimension (DTCD) area of the patterning mask, according to embodiments of the disclosure.

FIG. 5A illustrates a diagram of a DTCD area with a clear region for system bias compensation, according to various aspects of the present disclosure.

FIG. 5B illustrates a diagram of a DTCD area with a compensation region for deviation compensation, according to various aspects of the present disclosure.

FIG. 6A illustrates an intensity map of the patterning mask using secondary electron microscopy, according to embodiments of the disclosure.

FIG. 6B illustrates an intensity scanner map of a wafer formed by using the patterning mask, according to embodiments of the disclosure.

FIG. 6C illustrates an intensity map of the patterning mask using the patterning mask inspecting device, according to embodiments of the disclosure.

FIG. 7 illustrates a diagram of a dummy test critical dimension (DTCD) area with dummy patterns, according to embodiments of the disclosure.

FIG. 8 illustrates a diagram of a dummy test critical dimension (DTCD) area with dummy patterns, according to embodiments of the disclosure.

FIG. 9 illustrates a cross-sectional view of a structure of a portion of the patterning mask, according to embodiments of the disclosure.

FIG. 10 illustrates a flow diagram of a method for inspecting the patterning mask, according to embodiments of the disclosure.

FIG. 11 illustrates a block diagram of an example artificial intelligence (AI) engine, according to embodiments of the disclosure.

FIGS. 12A and 12B illustrate a computer system for implementing various methods, according to embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “being made of” may mean either “comprising” or “consisting of.” In the present disclosure, a phrase “one of A, B and C” means “A, B and/or C” (A, B, C, A and B, A and C, B and C, or A, B and C), and does not mean one element from A, one element from B and one element from C, unless otherwise described.

In some embodiments, in a lithography system, e.g., an EUV lithography system, a beam of EUV radiation is generated by an EUV radiation source, and the beam of EUV radiation is directed to an exposure device for projecting layout patterns of patterning masks onto photoresist layers disposed on one or more wafers. It would be desirable to inspect the patterning masks in order to improve photolithography patterns on the wafers.

Critical dimension uniformity (CDU) may be measured to inspect the patterning mask before the patterning mask is used in the lithographic process. In some embodiments, scanning electron microscopy (SEM) is used to image the surface of the patterning mask for measuring and monitoring the CDU of the patterning mask. However, the secondary electron microscopy image of SEM does not reflect the pre-dose mapper (pre-DOMA) map results of the scanner corresponding to the patterning mask. Embodiments of this disclosure provide improved methods and systems for inspecting the patterning mask by using an extreme ultraviolet (EUV) radiation beam to image the surface of the patterning mask, thereby improving the contrast of the image of the patterning mask. Artificial intelligence (AI) may further assist with monitoring the wafer pattern behavior based on images of the dummy patterns on the patterning mask and determining the CDU of the patterning mask. Furthermore, the system can be trained with patterning masks having known dummy patterns to improve the accuracy and efficiency for determining the CDU of the patterning mask and monitoring the wafer pattern behavior of the patterning mask.

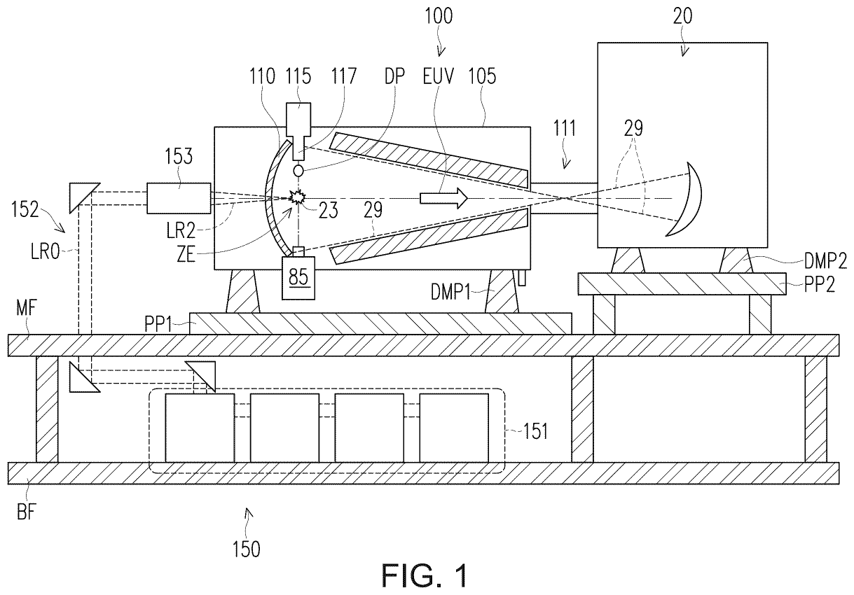

FIG. 1 illustrates a schematic view of an EUV lithography system with a laser-produced plasma (LPP) EUV radiation source, in accordance with some embodiments of the present disclosure. The EUV lithography system includes an EUV radiation source 100 (an EUV light source) to generate EUV radiation, an exposure device 20, such as a scanner, and an excitation laser source 150. As shown in FIG. 1, in some embodiments, the EUV radiation source 100 and the exposure device 20 are installed on a main floor MF of a clean room, while the excitation laser source 150 is installed in a base floor BF located under the main floor. Each of the EUV radiation source 100 and the exposure device 20 are placed over pedestal plates PP1 and PP2 via dampers DMP1 and DMP2, respectively. The EUV radiation source 100 and the exposure device 20 are coupled to each other by a coupling mechanism, which may include a focusing unit 111. In some embodiments, a lithography system includes the EUV radiation source 100 and the exposure device 20.

The lithography system is an EUV lithography system designed to expose a photoresist layer by EUV light (also interchangeably referred to herein as EUV radiation). The resist layer is a material sensitive to the EUV light. The EUV lithography system employs the EUV radiation source 100 to generate EUV light, such as EUV light having a wavelength ranging between about 1 nm and about 50 nm. In one particular example, the EUV radiation source 100 generates an EUV light with a wavelength centered at about 13.5 nm. In the present embodiment, the EUV radiation source 100 utilizes a mechanism of laser-produced plasma (LPP) to generate the EUV radiation.

The exposure device 20 includes various reflective optical components, such as convex/concave/flat mirrors, a mask holding mechanism including a mask stage, and a wafer holding mechanism, e.g., a substrate holding mechanism or a wafer stage. In some embodiments, the mask stage is included in a mask handling system and the mask handling system is included in or is coupled to the exposure device 20. In some embodiments, the wafer stage is included in a wafer table and the wafer table is included in or is coupled to the exposure device 20. The EUV radiation generated by the EUV radiation source 100 is guided by the reflective optical components onto a patterning mask secured on the mask stage. In some embodiments, the mask stage includes an electrostatic chuck (e-chuck) to secure the patterning mask. Because gas molecules absorb EUV light, the lithography system for the EUV lithography patterning is maintained in a vacuum or a low-pressure environment to avoid EUV intensity loss. A photoresist layer is disposed over the substrate. The EUV radiation generated by the EUV radiation source 100 is directed by the optical components to project the layout patterns of the patterning mask on the photoresist layer of the substrate. In some embodiments, after the exposure of the layout patterns of the mask on the photoresist layer of the substrate, the reticle is transferred out of the exposure device 20.

In the present disclosure, the terms patterning mask, photomask, mask, and reticle are used interchangeably. In addition, the terms resist and photoresist are used interchangeably. In some embodiments, the patterning mask is a reflective mask.

The exposure device 20 includes projection optics modules for imaging the pattern of the patterning mask onto a semiconductor substrate with a resist coated thereon secured on a substrate stage of the exposure device 20. The projection optics modules include reflective optics in some embodiments. The EUV radiation (EUV light) directed from the mask, carrying the image of the pattern defined on the mask, is collected and directed by the projection optics modules, e.g., mirrors, thereby forming an image of the layout patterns of the patterning mask on the resist.

In various embodiments of the present disclosure, the semiconductor substrate is a semiconductor wafer, such as a silicon wafer or other type of wafer to be patterned. The semiconductor substrate is coated with a photoresist layer sensitive to EUV light in disclosed embodiments. Various components including those described above are integrated together and are operable to perform lithography exposing processes. The lithography system may further include other modules or be integrated with (or be coupled with) other modules.

As shown in FIG. 1, the EUV radiation source 100 includes a droplet generator 115 and an LPP collector mirror 110, enclosed by a chamber 105. The droplet generator 115 generates a plurality of target droplets DP, which are supplied into chamber 105 through a nozzle 117. In some embodiments, the target droplets DP are tin (Sn), lithium (Li), or an alloy of Sn and Li. In some embodiments, the target droplets DP each have a diameter in a range from about 10 microns (μm) to about 100 μm. For example, in an embodiment, the target droplets DP are tin droplets, each having a diameter of about 10 μm, about 25 μm, about 50 μm, or any diameter between these values. In some embodiments, the target droplets DP are supplied through the nozzle 117 at a rate in a range from about 50 droplets per second (i.e., an ejection-frequency of about 50 Hz) to about 50,000 droplets per second (i.e., an ejection-frequency of about 50 kHz). For example, in an embodiment, the target droplets DP are supplied at an ejection frequency of about 50 Hz, about 100 Hz, about 500 Hz, about 1 kHz, about 10 kHz, about 25 kHz, about 50 kHz, or any ejection frequency between these frequencies. The target droplets DP are ejected through nozzle 117 and into a zone of excitation ZE (e.g., a target droplet location) at a speed in a range from about 10 meters per second (m/s) to about 100 m/s in various embodiments. For example, in an embodiment, the target droplets DP have a speed of about 10 m/s, about 25 m/s, about 50 m/s, about 75 m/s, about 100 m/s, or at any speed between these speeds.

The excitation laser beam LR2 generated by the excitation laser source 150 is a pulsed beam. The laser pulses of laser beam LR2 are generated by the excitation laser source 150. The excitation laser source 150 may include a laser generator 151, laser guide optics 152, and a focusing apparatus 153. In some embodiments, the laser generator 151 includes a carbon dioxide (CO₂) or a neodymium-doped yttrium aluminum garnet (Nd: YAG) laser source with a wavelength in the infrared region of the electromagnetic spectrum. For example, the excitation laser source 150 has a wavelength of 9.4 μm or 10.6 μm in an embodiment. The laser light beam LR0 generated by the excitation laser source 150 is guided by the laser guide optics 152 and focused, by the focusing apparatus 153, into the excitation laser beam LR2 that is introduced into the EUV radiation source 100. In some embodiments, in addition to CO₂ and Nd: YAG lasers, the laser beam LR2 is generated by a gas laser including an excimer gas discharge laser, helium-neon laser, nitrogen laser, transversely excited atmospheric (TEA) laser, argon ion laser, copper vapor laser, KrF laser or ArF laser; or a solid state laser including Nd: glass laser, ytterbium-doped glasses, ceramics laser, or ruby laser. In some embodiments, a non-ionizing laser beam LR1 (not shown) is also generated by the excitation laser source 150 and the laser beam LR1 is also focused by the focusing apparatus 153 to pre-heat a given target droplet by generating a pre-heat laser pulse.

In some embodiments, the excitation laser beam LR2 includes the pre-heat laser pulse and a main laser pulse. In such embodiments, the pre-heat laser pulse (interchangeably referred to herein as the “pre-pulse) is used to heat (or pre-heat) the given target droplet to create a low-density target plume with multiple smaller droplets, which is subsequently heated (or reheated) by the main laser pulse from the main laser, to generate increased emission of EUV light compared to when the pre-heat laser pulse is not used.

In various embodiments, the pre-heat laser pulses have a spot size of about 100 μm or less, and the main laser pulses have a spot size in a range of about 150 μm to about 300 μm. In some embodiments, the pre-heat laser and the main laser pulses have a pulse duration in the range from about 10 ns to about 50 ns, and a pulse frequency in the range from about 1 kHz to about 100 kHz. In various embodiments, the pre-heat laser and the main laser have an average power in the range from about 1 kilowatt (kW) to about 50 kW. The pulse frequency of the excitation laser beam LR2 is matched with the ejection frequency of the target droplets DP in an embodiment.

The laser beam LR2 is directed through windows (or lenses) into the zone of excitation ZE. The windows are made of a suitable material substantially transparent to the laser beams. The generation of the laser pulses is synchronized with the ejection of the target droplets DP through the nozzle 117. As the target droplets move through the excitation zone, the pre-pulses heat the target droplets and transform them into low-density target plumes. A delay between the pre-pulse and the main pulse is controlled to allow the target plume to form and expand to an optimal size and geometry. In various embodiments, the pre-pulse and the main pulse have the same pulse duration and peak power. When the main pulse heats the target plume, a high-temperature plasma plume 23 is generated. The plasma plume 23 emits EUV radiation 29, which is collected by the LPP collector mirror 110. The LPP collector mirror 110, an EUV collector mirror, further reflects and focuses the EUV radiation 29 for the lithography exposing processes performed by the exposure device 20. A droplet DP that does not interact with the laser pulses is captured by the droplet catcher 85. As shown in FIG. 1, the EUV radiation 29 from the LPP collector mirror 110 focuses at the focusing unit 111 between the EUV radiation source 100 and the exposure device 20. The EUV radiation 29 that enters from the focusing unit 111 into the exposure device 20 is consistent with EUV radiation that is originated from the focused point, e.g., a point source, in the focusing unit 111.

In some embodiments, the exposure device 20 is an integrated circuit lithography tool such as a stepper, scanner, step and scan system, direct write system, device using a contact and/or proximity mask, etc., provided with one or more optics for example, to illuminate a reticle with a beam of EUV light, to produce a patterned beam, and one or more reduction projection optics for projecting the patterned beam onto a semiconductor wafer to pattern the semiconductor wafer.

In some embodiments, the patterning mask is inspected before the patterning mask is used for projecting layout patterns of the patterning mask onto photoresist layers disposed on one or more wafers. For example, the EUV radiation 29 is directed to illuminate the patterning mask before the patterning mask is secured to the mask stage of the exposing device 20, such that an image of the surface of the patterning mask is generated to determine the critical dimension uniformity (CDU) of the patterning mask.

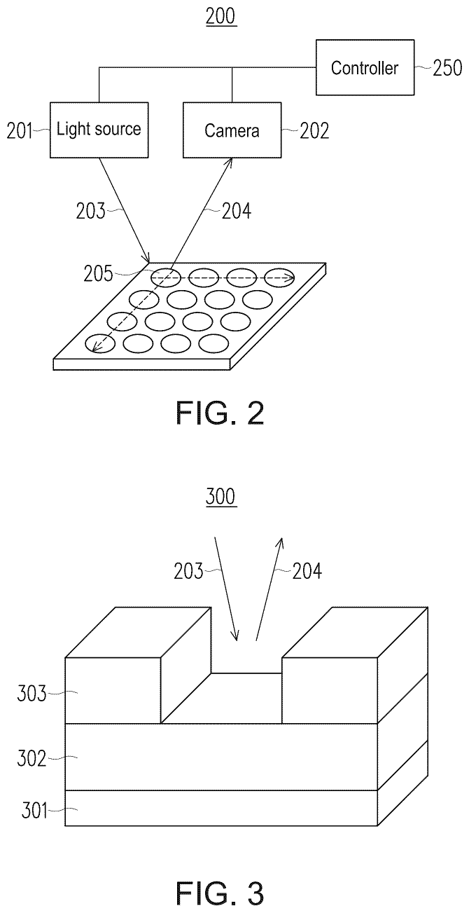

FIG. 2 illustrates a schematic view of a patterning mask inspecting device 200, in accordance with some embodiments of the present disclosure. The patterning mask inspecting device 200 includes an EUV light source 201, an image sensor 202, and a controller 250.

In some embodiments, the EUV light source 201, which is in consistent with the EUV radiation source 100 as shown in FIG. 1, provides an EUV radiation beam 203. The EUV radiation beam 203 is directed by one or more optics and radiated and/or incident to the top surface of a patterning mask 205. The EUV radiation beam 203 is reflected from the top surface of the patterning mask 205, and the reflected EUV radiation beam 204 is directed by one or more optics toward the image sensor 202 to generate an image of the surface of the patterning mask 205.

In some embodiments, the image sensor 202 is configured to construct the image of the surface of the patterning mask 205 by using the reflected EUV radiation beam 204 captured by the image sensor 202. In some embodiments, the image sensor 202 is a charge coupled device (CCD) camera that detects the reflected EUV radiation beam 204. In some embodiments, the generated image of the surface of the patterning mask 205 is an aerial image of the surface of the patterning mask 205.

In some embodiments, the image sensor 202 is electrically connected and/or coupled to a controller 250, which is configured to receive and process the generated image of the surface of the patterning mask 205. In some embodiments, the controller 250 performs one or more image processing and/or image recognition algorithms on the generated image of the surface of the patterning mask 205 and determines a critical dimension uniformity (CDU) of the patterning mask 205. In some embodiments, the controller 250 is a microcontroller unit configured to perform one or more image processing and/or image recognition algorithms on the generated image of the surface of the patterning mask 205 and monitor a wafer pattern behavior of the patterning mask 205.

In some embodiments, the EUV light source 201 is electrically connected and/or coupled to the controller 250, which is configured to control the EUV light source 201 for generating the EUV radiation beam 203.

FIG. 3 illustrates a perspective view of the structure 300 of a portion of the patterning mask 205, in accordance with some embodiments of the present disclosure. The structure 300 of the patterning mask 205 includes a substrate 301, a reflective layer 302 deposited on the substrate 301, and an absorber layer 303 deposited on the reflective layer 302.

In some embodiments, the patterning mask 205 is a reflective mask. The substrate 301 is made of a suitable material, such as a low thermal expansion material (LTEM) or fused quartz. In various examples, the LTEM includes TiO₂ doped SiO₂, or another suitable material with low thermal expansion.

In some embodiments, the reflective layer 302 includes reflective multiple layers (ML) deposited on the substrate 301. The reflective multiple layers may include a plurality of film pairs, such as molybdenum-silicon (Mo/Si) film pairs (e.g., a layer of molybdenum above or below a layer of silicon in each film pair). Alternatively, the reflective multiple layers may include molybdenum-beryllium (Mo/Be) film pairs, or other suitable materials that are configurable to highly reflect the EUV light.

In some embodiments, the absorber layer 303 is a tantalum boron nitride (TaBN) layer deposited over the reflective layer 302. The absorber layer 303 is patterned to define a layout pattern for projecting the layout pattern of the patterning mask 205 onto photoresist layers disposed on one or more wafers. Alternatively and/or additionally, another reflective layer (not shown) may be deposited over the ML and is patterned to define a layout pattern, thereby forming an EUV phase shift mask.

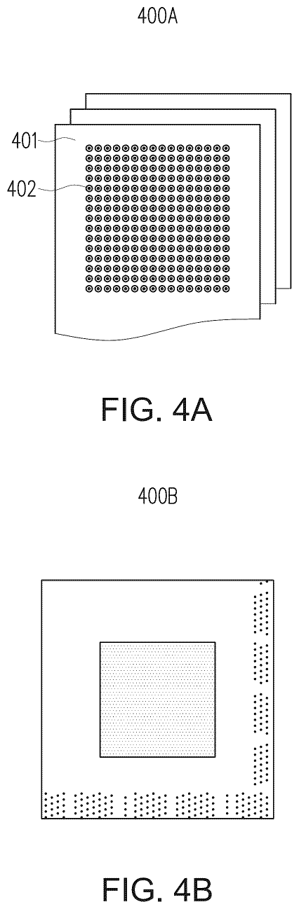

FIG. 4A illustrates an image 400A of the patterning mask 205, in accordance with some embodiments of the present disclosure.

In some embodiments, the image 400A of the patterning mask 205 includes a pattern 401. In some examples, the pattern 401 includes an array of vias 402.

In some embodiments, the image 400A of the patterning mask 205 is generated based on the reflected EUV radiation beam 204 detected by the image sensor 202.

In some embodiments, the controller 250 is configured to determine a critical dimension (CD) of the patterning mask 205 based on the image of the surface of the patterning mask 205. In some embodiments, the controller 250 is further configured to determine a critical dimension uniformity (CDU) of the patterning mask 205 based on the image of the surface of the patterning mask 205.

FIG. 4B illustrates a diagram of a dummy test critical dimension (DTCD) area 400B of the patterning mask 205, in accordance with some embodiments of the present disclosure.

In some embodiments, a main pattern defined by the patterning mask 205 is intended to define a layout pattern for projecting the layout pattern of the patterning mask 205 onto photoresist layers disposed on one or more wafers. In some embodiments, out of the area for the main pattern, a calibration zone is selected as a dummy test critical dimension (DTCD) area. For example, as shown in FIG. 4B, a DTCD area 400B of the patterning mask 205 is selected as the calibration zone and/or wafer behavior monitoring area.

In some embodiments, the dummy test critical dimension (DTCD) area is separated from the main pattern. In some embodiments, the DTCD area has a dimension in a range from about 5 μm to about 50 μm. In some embodiments, the DTCD area has a dimension of about 20 μm.

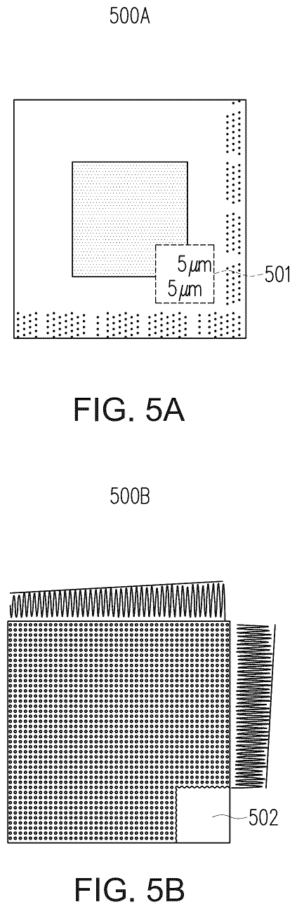

FIG. 5A illustrates a diagram of a dummy test critical dimension (DTCD) area with a clear region for system bias compensation, in accordance with some embodiments of the present disclosure. FIG. 5B illustrates a diagram of a DTCD area with a compensation region for deviation compensation, in accordance with some embodiments of the present disclosure.

In some embodiments, the detected signal of the reflected EUV radiation beam by the image sensor 202 is affected by the system bias, such as a process bias and a device bias. The process bias and the device bias cause the generated image of the surface of the patterning mask 205 based on the detected signal to have a low contrast. As shown in FIG. 5A, an image of the clear region 501 is generated based on the reflected EUV radiation beam 204 detected by the image sensor 202. The critical dimension (CD) process bias ΔCD_{process} and the CD device bias ΔCD_{device} are determined based on the image of the clear region 501 to improve the image contrast of the generated image of the surface of the patterning mask 205. In some embodiments, the CD modification ΔCD is determined by the CD process bias ΔCD_{process} and the CD device bias ΔCD_{device}. For example, the CD modification ΔCD is determined by below EQ. 1.

$$Δ CD = Δ {CD}_{process} + Δ {CD}_{device} \qquad EQ . 1$$

In some embodiments, the detected signal of the reflected EUV radiation beam is deviated by a tilting bias and an intensity bias. As shown in FIG. 5B, an image of a compensation region 502 is generated for deviation compensation based on the reflected EUV beam detected by the image sensor 202. The CD tilting bias and the CD intensity bias are determined based on the image of the compensation region 502. In some embodiments, the compensation region 502 is located at a corner of the patterning mask 205.

In some embodiments, the critical dimension (CD) determined by the controller 250 is properly modified and/or compensated by the CD modification, the CD tilting bias, and the CD intensity bias to improve the accuracy in the CD and CDU measurements.

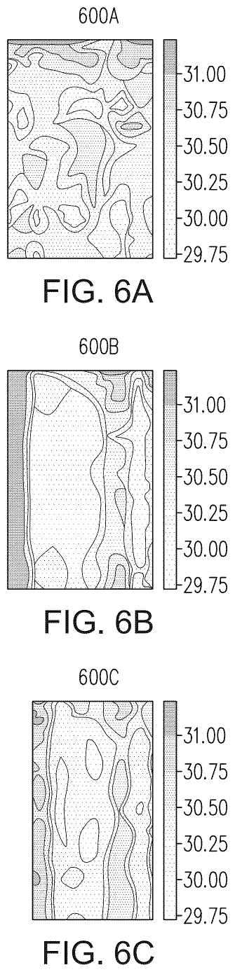

FIG. 6A illustrates an intensity map 600A of the patterning mask 205 using secondary electron microscopy, in accordance with some embodiments of the present disclosure. FIG. 6B illustrates an intensity scanner map 600B of a wafer formed by using the patterning mask 205, in accordance with some embodiments of the present disclosure. FIG. 6C illustrates an intensity map 600C of the patterning mask 205 using the patterning mask inspecting device 200, in accordance with some embodiments of the present disclosure.

In some embodiments, as shown in FIG. 6A, the intensity map 600A of the patterning mask 205 using secondary electron microscopy does not show all the details of the surface of the patterning mask 205 and is not suitable for measuring and/or monitoring the critical dimension uniformity (CDU) of the patterning mask 205. As shown in FIG. 6B, the intensity scanner map 600B shows a more detailed distribution of the CDU of the wafer formed by using the patterning mask 205. In some embodiments, the intensity map 600C of the patterning mask 205 using the patterning mask inspecting device 200 demonstrates a similar detailed distribution of the critical dimension uniformity as the intensity scanner map 600B. In some embodiments, the intensity map 600C of the patterning mask 205 using the patterning mask inspecting device 200 is configured to determine the CDU of the patterning mask 205 and monitor the wafer pattern behavior of the patterning mask 205.

In some embodiments, the controller 250 is configured to generate the intensity map 600C of the patterning mask 205 based on the image of the surface of the patterning mask 205. In some embodiments, the controller 250 is configured to determine the critical dimension uniformity (CDU) based on the intensity map 600C of the patterning mask 205.

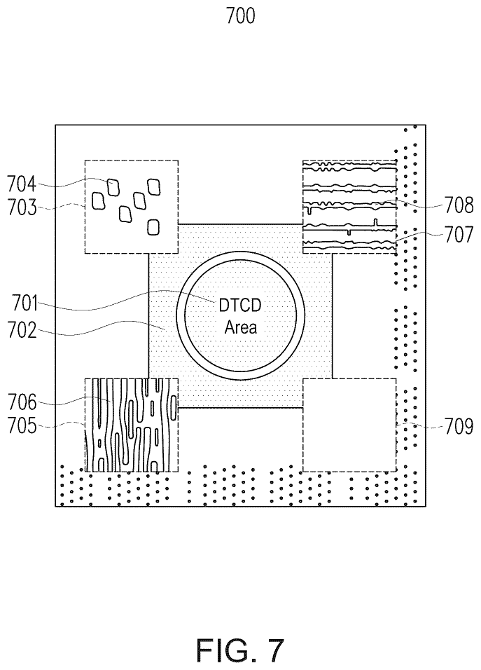

FIG. 7 illustrates a diagram of a dummy test critical dimension (DTCD) area 700 with dummy patterns, in accordance with some embodiments of the present disclosure.

In some embodiments, the DTCD area 700 includes a central DTCD area 701 and a peripheral DTCD area 702 surrounding the central DTCD area 701. In some embodiments, the central DTCD area 701 is used for determining the critical dimension uniformity (CDU) of the patterning mask 205.

In some embodiments, dummy patterns are introduced into the patterning mask 205 to monitor the wafer pattern behavior of the patterning mask 205. In some embodiments, the dummy patterns are positioned in the peripheral DTCD area 702. In some embodiments, the dummy patterns are positioned at corners of the peripheral DTCD area 702.

In some embodiments, the dummy patterns include a contact hole pattern. For example, the contact hole pattern is positioned at the left top corner of the peripheral DTCD area 702. A close-up view 703 of the contact hole pattern is shown in FIG. 7. The contact hole pattern includes a plurality of contact holes 704.

In some embodiments, the dummy patterns include a line space pattern. For example, the line space pattern is positioned at the left bottom corner of the peripheral DTCD area 702. A close-up view 705 of the line space pattern is shown in FIG. 7. The line space pattern includes a plurality of lines 706 spaced from each other.

In some embodiments, the dummy patterns include an inverse lithography technology (ILT) curvilinear pattern. For example, the ILT curvilinear pattern is positioned at the right top corner of the peripheral DTCD area 702. A close-up view 707 of the ILT curvilinear pattern is shown in FIG. 7. The ILT curvilinear pattern includes a plurality of curvilinear shapes 708.

In some embodiments, the dummy patterns include a clear region pattern. For example, the clear region pattern is positioned at the right bottom corner of the peripheral DTCD area 702. A close-up view 709 of the clear region pattern is shown in FIG. 7.

As discussed above and further emphasized here, the dummy patterns of FIG. 7 and positions of the dummy patterns are merely examples, which should not unduly limit the scope of the claims. One of ordinary skill in the art would recognize many variations, alternatives, and modifications of the dummy patterns.

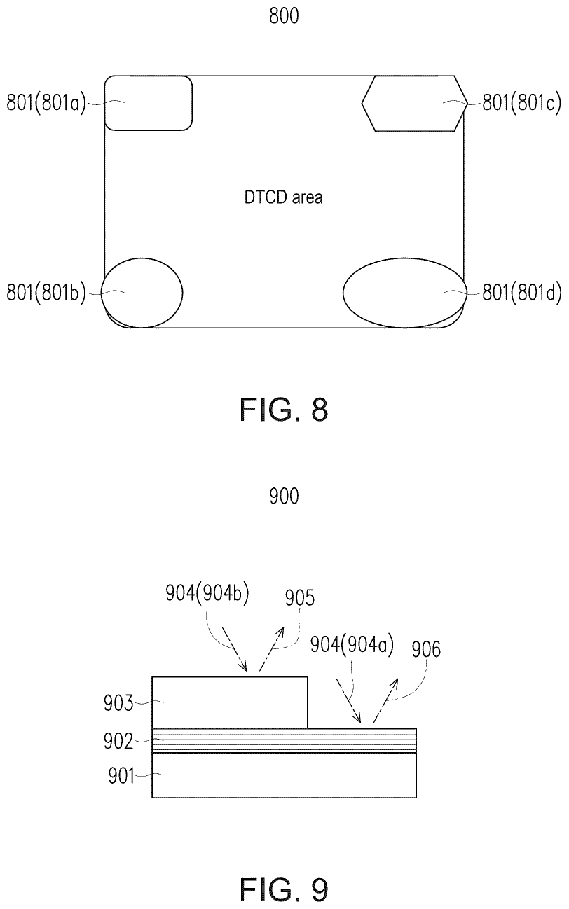

FIG. 8 illustrates a diagram of a dummy test critical dimension (DTCD) area 800 with dummy patterns, in accordance with some embodiments of the present disclosure.

In some embodiments, the DTCD area 800 includes a plurality of dummy patterns 801. The plurality of dummy patterns 801 may include different shapes of patterns other than the dummy patterns (e.g., 704, 706, and/or 708) as shown in FIG. 7. In some examples, as shown in FIG. 8, the plurality of dummy patterns 801 include a rectangular pattern 801a. In some examples, the plurality of dummy patterns 801 include a circular pattern 801b. In some examples, the plurality of dummy patterns 801 include a polygon pattern 801c. In some examples, the plurality of dummy pattern 801 include an elliptical pattern 801d. In some examples, the plurality of dummy pattern 801 include a square pattern (not shown).

In some embodiments, the plurality of dummy patterns 801 are positioned at corners of the DTCD area. In some embodiments, the DTCD area 800 is separated from the main pattern by a forbidden range, where the forbidden range is defined according to the feature size restrictions of the main pattern. In some embodiments, the square pattern 801a, the circular pattern 801b, the polygon pattern 801c, and the elliptical pattern 801d are applied to monitor the wafer pattern behavior of the patterning mask 205.

In some embodiments, the plurality of dummy patterns 801 include a clear region pattern. For example, the clear region pattern is applied to determine the critical dimension uniformity (CDU) of the patterning mask 205.

FIG. 9 illustrates a cross-sectional view of a structure 900 of a portion of the patterning mask 205, in accordance with some embodiments of the present disclosure. The structure 900 of the portion of the patterning mask 205 includes a substrate 901, a reflective layer 902 deposited on the substrate 901, and an absorber layer 903 deposited on the reflective layer 902. The substrate 901, the reflective layer 902, and the absorber layer 903 are consistent with the substrate 301, the reflective layer 302, and the absorber layer 303 of FIG. 3, respectively.

In some embodiments, as shown in FIG. 9, a radiation beam 904 originates from an EUV radiation source, e.g., the EUV radiation source 100 of FIG. 1 and/or the EUV light source 201 of FIG. 2. The radiation beam 904 is directed to the top surface of a patterning mask 205. A portion 904a of the radiation beam 904 is reflected by the top surface of the reflective layer 902 when the portion 904a of the radiation beam 904 is incident onto the top surface of the reflective layer 902, and the reflected EUV radiation beam 906 is directed to an image sensor (e.g., the image sensor 202 of FIG. 2). In some embodiments, a reflective rate Rᵣ of the radiation beam 904 on the top surface of the reflective layer 902 is in a range from about 50% to about 100%. In some embodiments, the reflective rate Rᵣ of the radiation beam 904 on the top surface of the reflective layer 902 is about 68%.

In some embodiments, the patterning mask 205 is a binary intensity mask (BIM). For example, a portion 904b of the radiation beam 904 is completely absorbed by the top surface of the absorber layer 903 when the portion 904b of the radiation beam 904 is incident onto the top surface of the absorber layer 903. That is, a reflective rate Rₐ of the absorber layer 903 on the top surface of the absorber layer 903 is about zero. The absorber layer 903 is patterned, such that the reflected EUV radiation beam 906 is directed to and/or detected by an image sensor (e.g., the image sensor 202 of FIG. 2) to generate an image of the surface of the patterning mask 205.

Alternatively, in some embodiments, the patterning mask 205 is a phase shift mask (PSM). For example, the portion 904b of the radiation beam 904 is partially absorbed by the top surface of the absorber layer 903 when the portion 904b of the radiation beam 904 is incident onto the top surface of the absorber layer 903. The portion 904b of the radiation beam 904 is partially reflected by the top surface of the absorber layer 903 when the portion 904b of the radiation beam 904 is incident onto the top surface of the absorber layer 903, and the reflected EUV radiation beam 905 is also directed to the image sensor (e.g., the image sensor 202 of FIG. 2). A reflective rate Rₐ₁ of the absorber layer 903 on the top surface of the absorber layer 903 is in a range from about 0% to about 10%. In some examples, the reflective rate Rₐ₁ of the absorber layer 903 on the top surface of the absorber layer 903 is about 5%.

In some embodiments, a phase shift between the reflected EUV radiation beam 905 and the reflected EUV radiation beam 906 is controlled by adjusting the thickness of the absorber layer 903 to improve the image generated by the image sensor 202. In some embodiments, the thickness of the absorber layer 903 is selected in a range from about 5 nm to 25 nm, such that the phase shift between the reflected EUV radiation beam 905 and the reflected EUV radiation beam 906 is about 180° to further improve the image contrast.

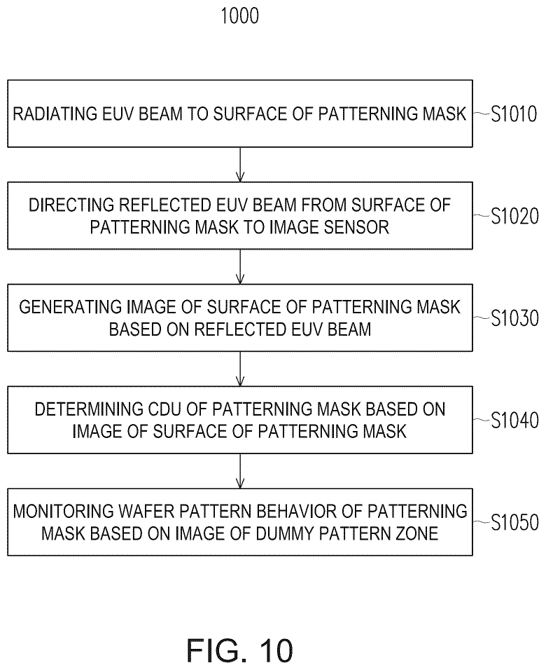

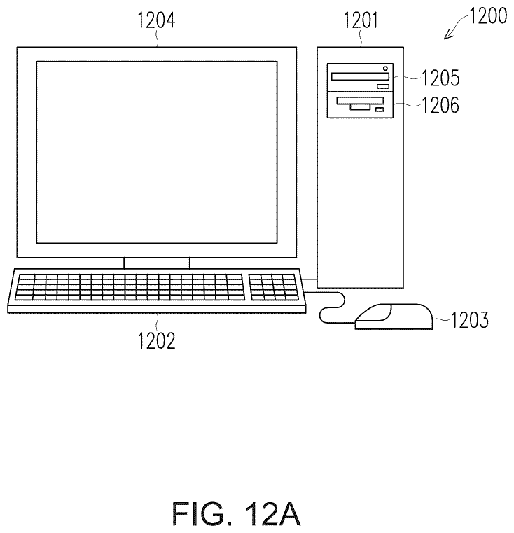

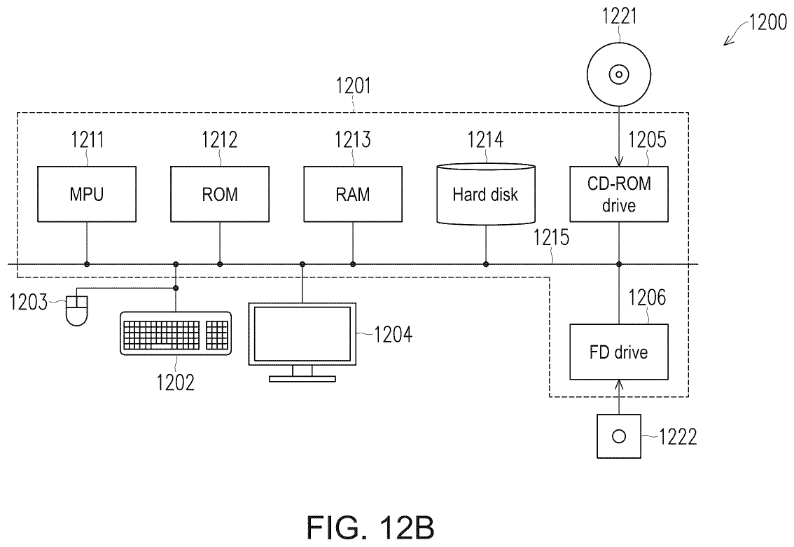

FIG. 10 illustrates a flow diagram of a method 1000 for inspecting the patterning mask 205, in accordance with some embodiments of the present disclosure. The method 1000 or a portion of the method 1000 is performed by a controller (e.g., Ref. No. 250 of FIG. 2). In some embodiments, the method 1000 or a portion of the method 1000 is performed and/or is controlled by a computer system 1200 described below with respect to FIGS. 12A and 12B. The method 1000 is merely an example, and is not intended to limit the present disclosure and what is claimed. Additional operations can be provided before, during, and after the method 1000, and some operations described can be replaced, eliminated, or moved around for additional embodiments of the method 1000.

In some embodiments, the method 1000 includes an operation S1010 as shown in FIG. 10. In operation S1010, an extreme ultraviolet (EUV) beam 203 is radiated to the surface of the patterning mask 205 as shown in FIG. 2.

In some embodiments, the EUV light source 201 is electrically connected and/or coupled to the controller 250, which is configured to control the EUV light source 201 for generating the EUV radiation beam 203 and radiating the extreme ultraviolet (EUV) beam 203 to the surface of the patterning mask 205.

In some embodiments, the method further includes an operation S1020 as shown in FIG. 10. In operation S1020, a reflected EUV radiation beam 204 from the surface of the patterning mask 205 is directed to an image sensor 202 as shown in FIG. 2.

In some embodiments, the method 1000 further includes an operation S1030 as shown in FIG. 10. In operation S1030, an image of the surface of the patterning mask 205 is generated based on the reflected EUV radiation beam 204.

In some embodiments, the image sensor 202 is electrically connected and/or coupled to the controller 250, which is configured to receive and process the generated image of the surface of the patterning mask 205. In some embodiments, the controller 250 performs one or more image processing and/or image recognition algorithms on the generated image of the surface of the patterning mask 205 and determines a critical dimension uniformity (CDU) of the patterning mask 205. In some embodiments, the controller 250 is a microcontroller unit configured to perform one or more image processing and/or image recognition algorithms on the generated image of the surface of the patterning mask 205 and monitor the wafer pattern behavior of the patterning mask 205.

In some embodiments, the method further includes an operation S1040 as shown in FIG. 10. In operation S1040, a critical dimension uniformity (CDU) of the patterning mask 205 is determined based on the image of the surface of the patterning mask 205.

In some embodiments, the surface of the patterning mask 205 includes a calibration zone. In some embodiments, the image of the surface of the patterning mask 205 is calibrated based on an image of the calibration zone by the controller 250. For example, the controller 250 is configured to determine a system bias, a tilt bias, and an intensity bias based on the image of the calibration zone. The controller 250 is further configured to calibrate the image of the surface of the patterning mask 205 based on the system bias, the tilt bias, and the intensity bias.

In some embodiments, the surface of the patterning mask 205 includes a dummy pattern zone and the method further includes an operation S1050 as shown in FIG. 10. In operation S1050, a wafer pattern behavior of the patterning mask 205 is monitored based on the image of the dummy pattern zone of the patterning mask 205.

In some embodiments, the dummy pattern zone includes at least one of a contact hole pattern, a line space pattern, a curvilinear pattern, and a clear region pattern as shown in FIG. 7.

In some embodiments, the dummy pattern zone includes at least one of a square pattern 801a, the circular pattern 801b, the polygon pattern 801c, and the elliptical pattern 801d as shown in FIG. 8.

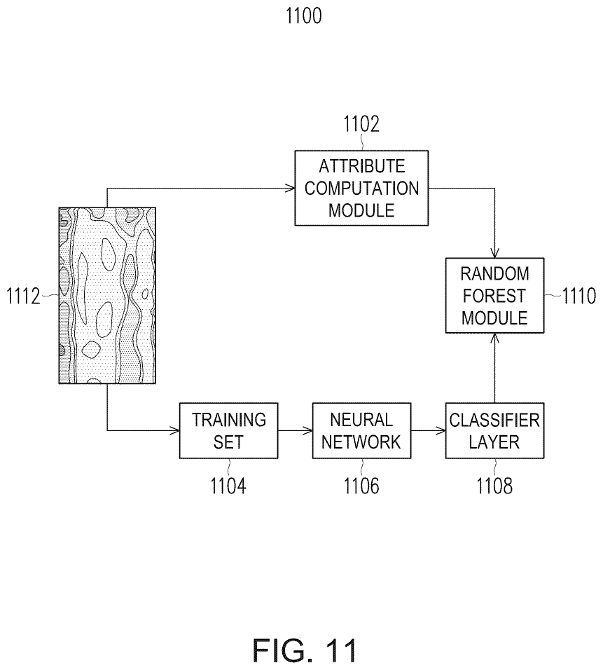

FIG. 11 illustrates a block diagram of an example artificial intelligence (AI) engine 1100, in accordance with some embodiments of the present disclosure. In some embodiments, the AI engine 1100 is implemented as a part of method 1000 of FIG. 10. As shown in FIG. 11, the AI engine 1100 comprises an attribute computation module 1102, a training set 1104, a neural network 1106, a classifier layer 1108, and a random forest module 1110.

In some embodiments, an image 1112 is fed into the AI engine 1100 and received by the attribute computation module 1102 and training set 1104 in parallel. In an upper portion of the AI engine 1100, the attribute computation module 1102 may calculate attributes of the image 1112 such as the critical dimension (CD), the image contrast, the shapes of the dummy pattern, and the size of the dummy pattern, etc. While in a lower portion of the AI engine, the training set 1104 provides suitable images for comparative analysis with the image 1112. The training set 1104 provides an example patterning mask image, which contains different dummy patterns on the surface of the patterning mask that previously occurred and were saved in a database. The example patterning mask image is processed by the neural network 1106 (e.g., a ResNet 18 network) to generate attributes. In some embodiments, the neural network 1106 includes at least one convolution layer and/or a depth-wise separable convolution layer for computing attributes. In some embodiments, there are a large set of attributes, in which case the classifier layer 1108 determines and selects the best attributes for additional analysis. In an embodiment, the classifier layer 1108 includes at least one fully connected (FC) layer for attribute selection. The classifier layer 1108 is implemented as multiple stages, each of which may reduce the number of attributes. The classifier layer 1108 determines and outputs a detection probability (embedded with other attributes), which is connected to the random forest module 1110 to output a final detection probability. Therefore, the random forest module 1110 mixes or combines both outputs of the attribute computation module 1102 and the classifier layer 1108 in generating the final detection probability. The final detection probability is used to determine the detectability of dummy patterns (e.g., a probability of one means detection, while a probability of zero means no detection) on the surface of the patterning mask 205. Thus, the final detection probability may be used in method 1000 to help optimize or retrain the monitoring process of the wafer pattern behavior of the patterning mask.

The upper portion of the AI engine 1100 containing the attribute computation module 1102 is sometimes called a machine learning portion, while the lower portion of the AI engine 1100 containing the training set 1104, the neural network 1106, and the classifier layer 1108 may be called a deep learning portion. The image 1112 may represent a simulated image or an actual inspection image (e.g., when the AI engine 1100 is being trained based on a database which includes images of patterning masks having known dummy patterns on the surface of patterning masks, in which case the output detection probability may determine the effectiveness of the AI engine 1100). The AI engine 1100 determines the critical dimension uniformity (CDU) of the patterning mask based on the image of the patterning mask. In addition, the AI engine 1100 may also help optimize the monitoring process of the wafer pattern behavior of the patterning mask using the final detection probability.

It is important to identify the defect of the patterning mask before the patterning mask is used in the lithographic process, such that corrective actions may be taken to reduce or eliminate these defects from future wafers. For example, when the CDU of the patterning mask is determined to be below pre-determined criteria or the wafer pattern behavior of a specific dummy pattern is not as expected, a cleaning process may be made to the patterning mask. In some examples, the patterning mask is taken out of service, and design modifications are needed for the patterning mask. In some examples, when the specific dummy pattern is determined to be not suitable for the patterning mask, the patterning mask is modified to have a different pattern.

FIGS. 12A and 12B illustrate a computer system 1200 for implementing various methods described herein, in accordance with some embodiments of the present disclosure. In some embodiments, the computer system 1200 is used for performing the functions of the controller 250 of FIG. 2, steps of method 1000 of FIG. 10, and the functions of AI engine 1100 of FIG. 11

FIG. 12A is a schematic view of a computer system that performs the functions of a device for inspecting a patterning mask. All of or a part of the processes, methods, and/or operations of the foregoing embodiments can be realized using computer hardware and computer programs executed thereon. In FIG. 12A, a computer system 1200 is provided with a computer 1201 including an optical disk read-only memory (e.g., CD-ROM or DVD-ROM) drive 1205 and a magnetic disk drive 1206, a keyboard 1202, a mouse 1203, and a monitor 1204.

FIG. 12B is a diagram showing an internal configuration of the computer system 1200. In FIG. 12B, the computer 1201 is provided with, in addition to the optical disk drive 1205 and the magnetic disk drive 1206, one or more processors, such as a micro processing unit (MPU) 1211, a ROM 1212 in which a program such as a boot-up program is stored, a random access memory (RAM) 1213 that is connected to the MPU 1211 and in which a command of an application program is temporarily stored and a temporary storage area is provided, a hard disk 1214 in which an application program, a system program, and data are stored, and a bus 1215 that connects the MPU 1211, the ROM 1212, and the like. Note that the computer 1201 may include a network card (not shown) for providing a connection to a LAN.

The program for causing the computer system 1200 to execute the functions for inspecting the patterning mask in the foregoing embodiments may be stored in an optical disk 1221 or a magnetic disk 1222, which are inserted into the optical disk drive 1205 or the magnetic disk drive 1206, and transmitted to the hard disk 1214. Alternatively, the program may be transmitted via a network (not shown) to the computer 1201 and stored in the hard disk 1214. At the time of execution, the program is loaded into the RAM 1213. The program may be loaded from the optical disk 1221 or the magnetic disk 1222, or directly from a network. The program does not necessarily have to include, for example, an operating system (OS) or a third-party program to cause the computer 1201 to execute the functions of the control system for inspecting the patterning mask in the foregoing embodiments. The program may only include a command portion to call an appropriate function (module) in a controlled mode and obtain desired results.

The novel processing systems and the methods according to the present disclosure provide an improved device and methods for inspecting the patterning masks by using an extreme ultraviolet (EUV) radiation beam to image the surface of the patterning mask, thereby improving the image contrast of the image of the patterning mask. Embodiments of the disclosure provide systems and methods using artificial intelligence (AI) to assist with monitoring the wafer pattern behavior based on images of the dummy patterns on the patterning mask and determining the CDU of the patterning mask. Consequently, accuracy and efficiency for determining the CDU of the patterning mask and monitoring the wafer pattern behavior of the patterning mask can be improved.

According to some embodiments of the present disclosure, a method for inspecting a patterning mask includes radiating an extreme ultraviolet (EUV) beam to a surface of the patterning mask and directing a reflected EUV beam from the surface of the patterning mask to an image sensor. The method further includes generating an image of the surface of the patterning mask based on the reflected EUV beam and determining a critical dimension uniformity (CDU) of the patterning mask based on the image of the surface of the patterning mask. In an embodiment, the surface of the patterning mask includes a calibration zone, and the method further includes calibrating the image of the surface of the patterning mask based on an image of the calibration zone. In an embodiment, calibrating the image of the surface of the patterning mask includes determining a system bias based on the image of the calibration zone; determining a tilt bias based on the image of the calibration zone; determining an intensity bias based on the image of the calibration zone; and calibrating the image of the surface of the patterning mask based on the system bias, the tilt bias, and the intensity bias. In an embodiment, the surface of the patterning mask includes a dummy pattern zone, and the method further includes monitoring a wafer pattern behavior of the patterning mask based on an image of the dummy pattern zone. In an embodiment, the dummy pattern zone includes at least one of a contact hole pattern, a line space pattern, a curvilinear pattern, and a clear region pattern. In an embodiment, the dummy pattern zone includes a circular pattern, a square pattern, a rectangular pattern, an elliptical pattern, or a polygon pattern. In an embodiment, the patterning mask includes a substrate, a reflective layer deposited on the substrate, and an absorber layer deposited on the reflective layer, wherein the absorber layer defines a pattern for the patterning mask. In an embodiment, the reflective layer includes reflective multiple layers (ML). In an embodiment, a reflection rate of the absorber layer is in a range from about 0% to about 10%; and a reflection rate of the reflective layer is in a range from about 50% to about 100%. In an embodiment, the patterning mask is a phase shift EUV mask. In an embodiment, the EUV beam has a wavelength of about 13.6 nm.

According to some embodiments of the present disclosure, a method for monitoring a wafer pattern behavior of a patterning mask includes radiating an extreme ultraviolet (EUV) beam to a surface of the patterning mask, and collecting an image of a dummy pattern zone of the patterning mask based on a reflected EUV beam from the surface of the patterning mask. The method further includes providing the image of the dummy pattern zone of the patterning mask to an artificial intelligence engine, and determining, by the artificial intelligence engine, the wafer pattern behavior of the patterning mask based on the image of the dummy pattern zone of the patterning mask. The method also includes determining a critical dimension uniformity (CDU) of the patterning mask based on the image of the dummy pattern zone of the patterning mask includes.

According to some embodiments of the present disclosure, a device for inspecting a patterning mask includes an image sensor, an extreme ultraviolet (EUV) beam source, a processor; and a non-transitory computer readable storage medium storing a program. The processor is programmed to radiate the EUV beam from the EUV beam source to a surface of the patterning mask, and direct a reflected EUV beam from the surface of the patterning mask to the image sensor. The processor is further programmed to generate an image of the surface of the patterning mask based on the reflected EUV beam and determine a critical dimension uniformity (CDU) of the patterning mask based on the image of the surface of the patterning mask.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for inspecting a patterning mask, comprising:
radiating an extreme ultraviolet (EUV) beam to a surface of the patterning mask;
directing a reflected EUV beam from the surface of the patterning mask to an image sensor;
generating an image of the surface of the patterning mask based on the reflected EUV beam; and
determining a critical dimension uniformity (CDU) of the patterning mask based on the image of the surface of the patterning mask.

2. The method according to claim 1, wherein the surface of the patterning mask includes a calibration zone, and the method further comprises:
calibrating the image of the surface of the patterning mask based on an image of the calibration zone.

3. The method according to claim 2, wherein calibrating the image of the surface of the patterning mask comprises:
determining a system bias based on the image of the calibration zone;
determining a tilt bias based on the image of the calibration zone;
determining an intensity bias based on the image of the calibration zone; and
calibrating the image of the surface of the patterning mask based on the system bias, the tilt bias, and the intensity bias.

4. The method according to claim 1, wherein the surface of the patterning mask includes a dummy pattern zone, and the method further comprises:
monitoring a wafer pattern behavior of the patterning mask based on an image of the dummy pattern zone.

5. The method according to claim 4, wherein the dummy pattern zone includes at least one of a contact hole pattern, a line space pattern, a curvilinear pattern, and a clear region pattern.

6. The method according to claim 4, wherein the dummy pattern zone includes a circular pattern, a square pattern, a rectangular pattern, an elliptical pattern, or a polygon pattern.

7. The method according to claim 1, wherein the patterning mask includes a substrate, a reflective layer deposited on the substrate, and an absorber layer deposited on the reflective layer, wherein the absorber layer defines a pattern for the patterning mask.

8. The method according to claim 7, wherein the reflective layer includes reflective multiple layers.

9. The method according to claim 7, wherein:
a reflection rate of the absorber layer is in a range from 0% to 10%; and
a reflection rate of the reflective layer is in a range from 50% to 100%.

10. The method according to claim 1, wherein the patterning mask is a phase shift EUV mask.

11. The method according to claim 1, wherein the EUV beam has a wavelength of about 13.6 nm.

12. A method for monitoring a wafer pattern behavior of a patterning mask, comprising:
radiating an extreme ultraviolet (EUV) beam to a surface of the patterning mask;
collecting an image of a dummy pattern zone of the patterning mask based on a reflected EUV beam from the surface of the patterning mask;
providing the image of the dummy pattern zone of the patterning mask to an artificial intelligence engine;
determining, by the artificial intelligence engine, the wafer pattern behavior of the patterning mask based on the image of the dummy pattern zone of the patterning mask; and
determining a critical dimension uniformity (CDU) of the patterning mask based on the image of the dummy pattern zone of the patterning mask.

13. The method according to claim 12, wherein the dummy pattern zone of the patterning mask includes at least one of a contact hole pattern, a line space pattern, a curvilinear pattern, and a clear region pattern.

14. The method according to claim 12, wherein the dummy pattern zone of the patterning mask includes at least one of a circular pattern, a square pattern, a rectangular pattern, an elliptical pattern, a polygon pattern, and a clear region pattern.

15. The method according to claim 12, wherein the patterning mask includes a substrate, a reflective layer deposited on the substrate, and an absorber layer deposited on the reflective layer, wherein the absorber layer defines a pattern for the patterning mask.

16. The method according to claim 12, wherein the patterning mask is a phase shift EUV mask.

17. A device for inspecting a patterning mask, comprising:
an image sensor;
an extreme ultraviolet (EUV) beam source;
a processor; and
a non-transitory computer-readable storage medium storing a program, wherein the processor is programmed to control:
radiating an EUV beam from the EUV beam source to a surface of the patterning mask;
directing a reflected EUV beam from the surface of the patterning mask to the image sensor;
generating an image of the surface of the patterning mask based on the reflected EUV beam; and
determining a critical dimension uniformity (CDU) of the patterning mask based on the image of the surface of the patterning mask.

18. The device according to claim 17, wherein the surface of the patterning mask includes a dummy pattern zone, and the processor is programmed to control monitoring a wafer pattern behavior of the patterning mask based on an image of the dummy pattern zone.

19. The device according to claim 17, wherein the surface of the patterning mask includes a calibration zone, and the processor is programmed to control:
calibrating the image of the surface of the patterning mask based on an image of the calibration zone.

20. The device according to claim 19, wherein calibrating the image of the surface of the patterning mask comprises:
determining a system bias based on the image of the calibration zone;
determining a tilt bias based on the image of the calibration zone;
determining an intensity bias based on the image of the calibration zone; and
calibrating the image of the surface of the patterning mask based on the system bias, the tilt bias, and the intensity bias.
